(19) United States
(12) Patent Application Publication
(10) Pub. No.: US 2002/0177081 A1
(43) Pub. Date: Nov. 28, 2002

(54) Substrate for forming a resist pattern, process for producing the substrate and process for forming a resist pattern of the chemical amplification type

(76) Inventors: Nobunori Abe, Yokohama-shi (JP); Kakuei Ozawa, Kamakura-shi (JP)

Correspondence Address: ARMSTRONG,WESTERMAN & HATTORI, LLP, 1725 K STREET, NW., SUITE 1000, WASHINGTON, DC, 20006, US

(21) Appl. No.: 10/098,173

(22) Filed: Mar. 15, 2002

(30) Foreign Application Priority Data
Mar. 21, 2001 (JP) 81510/2001
Mar. 30, 2001 (JP) 98597/2001

(51) Int. Cl. G03F 7/00

(52) U.S. Cl. 430/314; 430/14; 430/323; 430/324; 430/330; 430/449

(57) ABSTRACT

A substrate for forming a resist pattern comprising a resist film of the chemical amplification type and a coating film which is formed on the resist film, comprises an amorphous polyolefin or a polymer having an aromatic ring and has the same thickness as that of the resist film or smaller; and a process for forming a resist pattern of the chemical amplification type, which comprises steps of forming a pattern of a latent image in the resist film by irradiation with an ionizing radiation and converting the pattern of a latent image into a pattern of a visible image by a development treatment.

Deterioration in sensitivity and resolution with time during storage and transportation of the resist film of the chemical amplification type formed on the substrate is suppressed, the sectional shape is rectangular and a resist pattern having excellent dimensional fidelity is provided.

### BACKGROUND OF THE INVENTION

1. Field of the Invention

The present invention relates to a substrate for forming a resist pattern, a process for producing the substrate, a composition for forming a coating film on a resist film of a chemical amplification type, a process for forming a resist pattern of a chemical amplification type and a process for producing a semiconductor device or a member used for producing a semiconductor device. More particularly, the present invention relates to a substrate for forming a resist pattern which suppresses deterioration in sensitivity and resolution with time during storage and transportation of a resist film of the chemical amplification type formed on the substrate, has a rectangular sectional shape and provides a resist pattern of the chemical amplification type having excellent dimensional fidelity, a process for forming the substrate, a composition for forming a coating film on a resist film of the chemical amplification type which is used for the above substrate for forming a resist pattern, a process for forming a resist pattern of the chemical amplification type which uses the substrate for forming a resist pattern and advantageously applied for producing a semiconductor device or a photomask which is a member used for producing a semiconductor device and a process for producing a semiconductor device or a member used for producing a semiconductor device.

2. Description of Related Art

Recently, micro-working in accordance with the photolithography is used as a means for improving the degree of integration of semiconductor devices. The micro-working in accordance with the photolithography has been improved by using a light source having a shorter wavelength for irradiation. For example, g ray has been replaced by i ray, which has been replaced by KrF excimer laser and KrF excimer laser has, in turn, been replaced by ArF excimer laser. As the micro-working in accordance with the photolithography is improved, it is required that photomasks used for the working has the property suitable for the improved micro-working. As the resist used for preparing the photomask, for example, PBS RESIST [a trade name; manufactured by CHISSO Corporation], CMS RESIST [a trade name; manufactured by TOSO Corporation] and electron beam resists of the ZEP series [a trade name; manufactured by ZEON Corporation] are used. However, a resist of the chemical amplification type which exhibits higher sensitivity and higher resolution is required for the micro-working of the next generation.

For producing a photomask, a rectangular substrate having a large size is used. In contrast, a circular substrate is coated with a resist in conventional processes for producing semiconductors devices. For coating a rectangular substrate having a large size with a resist, a high degree of technology is required since the formed film must be uniform in the entire portions of the substrate including corner portions of the rectangle. Due to this requirement in the production of photomasks, the formation of a resist film on a substrate and the formation of a pattern are occasionally conducted in separate companies. In this case, resists are supplied to the market in the form of resist films formed on substrates.

However, it is known that a resist of the chemical amplification type, whose application to the mask of the next generation has been studied, exhibits marked deterioration in sensitivity and resolution with time due to contaminants in the environment during storage and transportation of the resist film formed on a substrate. The resist of the chemical amplification type utilizes the catalytic reaction with an acid taking place in the presence of a minute amount of the acid and the above deterioration is also related to this reaction mechanism. In other words, it is difficult that the resist film is kept with stability until it is used for the step of forming a pattern.

### SUMMARY OF THE INVENTION

Under the above situation, the present invention has a first object of providing a substrate for forming a resist pattern which suppresses deterioration in sensitivity and resolution with time during storage and transportation of a resist film of the chemical amplification type formed on the substrate, has a rectangular sectional shape and provides a resist pattern of the chemical amplification type having excellent dimensional fidelity and a second object of providing a process for producing the above substrate.

The present invention has a third object of providing a composition for forming a coating film on a resist film of the chemical amplification type which is used for the above substrate for forming a resist pattern, a fourth object of providing a process for forming a resist pattern of the chemical amplification type which uses the substrate for forming a resist pattern and can be advantageously applied for producing a semiconductor device or a photomask which is a member used for producing a semiconductor device and a fifth object of providing a process for producing a semiconductor device or a member used for producing a semiconductor device.

In the study by the present inventors to suppress the deterioration in sensitivity and resolution of a resist film of the chemical amplification type with time, a coating film was formed on the resist film and it was found that a coating film comprising an amorphous polyolefin was effective (Japanese Patent Application Laid-Open No. Heisei 6(1994)-95397). Forming a coating film on the resist film has a problem in that the surface of the resist film tends to become insoluble due to the contact of the resist film with impurities in the atmosphere such as amines and protrusions of a hood shape are formed. In the specification of this application, it is proposed that this problem is overcome by forming a coating film of an amorphous polyolefin on a resist film. In accordance with the process for forming a pattern described in the examples of the above specification, a coating film having a thickness greater than the thickness of the resist film is formed.

However, it was confirmed by the present inventors that the thick coating film formed above causes a problem in that an excellent pattern shape cannot be obtained and resolution deteriorates when particle beams such as electron beams, which are an energy source conventionally used for producing photomasks, are used for forming a pattern since scattering of particles takes place while the particles pass through the coating film. In the above process, a coating fluid prepared by dissolving an amorphous polyolefin into a suitable solvent is applied to a resist film and a coating film is formed. In this connection, the above process has a further drawback in that an excellent coating film is not formed and a sufficient effect is not exhibited when the combination of the resist film and the coating film is not suitable.

The present inventors further studied the coating film which can effectively suppress the deterioration in sensitivity and resolution of the resist film of the chemical amplification type with time, provides an excellent resist pattern and exhibits an excellent coating property and it was found that an excellent pattern could be obtained and the deterioration in sensitivity and resolution after the resist film was left standing could be suppressed by forming a coating film of a specific compound on the resist film and adjusting the thickness of the coating film to a value which is the same as or smaller than the thickness of the resist film.

The present invention has been completed based on the knowledge.

The present invention provides:

(1) A substrate for forming a resist pattern comprising a resist film of a chemical amplification type and a coating film which is formed on the resist film, comprises an amorphous polyolefin or a polymer having an aromatic ring and has a thickness which is a same as or smaller than a thickness of the resist film;

(2) A process for producing a substrate for forming a resist pattern, which comprises steps of (A) forming a resist film of a chemical amplification type on a substrate for working and (B) forming on the resist film a coating film which comprises an amorphous polyolefin or a polymer having an aromatic ring and has a thickness which is a same as or smaller than a thickness of the resist film;

(3) A composition for forming a coating film on a resist film of a chemical amplification type, which comprises an amorphous polyolefin or a polymer having an aromatic ring and a solvent;

(4) A process for forming a resist pattern of a chemical amplification type, which comprises steps of (C) forming a pattern of a latent image in a resist film of a chemical amplification type by irradiation of a substrate for forming a resist pattern described above with an ionizing radiation and (D) converting the pattern of a latent image into a pattern of a visible image by a development treatment of the resist film having the pattern of a latent image; and

(5) A process for producing a semiconductor device or a member used for producing a semiconductor device, which comprises steps of forming a resist pattern as described above, etching a substrate and removing the resist pattern, successively.

### DESCRIPTION OF THE PREFERRED EMBODIMENTS

The substrate for forming a resist pattern comprises a resist film of a chemical amplification type and a coating film which is formed on the resist film, comprises an amorphous polyolefin or a polymer having an aromatic ring and has a thickness which is the same as or smaller than the thickness of the resist film.

As the resist composition of the chemical amplification type used for forming the above resist film of the chemical amplification type, any of a positive type composition and a negative type composition can be used.

The positive type resist composition of the chemical amplification type is not particularly limited. Examples of such a composition include conventional compositions such as resist compositions comprising as the essential components a resin which exhibits varying solubility into an alkali by the effect of an acid and a compound generating an acid by irradiation with an ionizing radiation. The negative type resist composition of the chemical amplification type is not particularly limited. Examples of such a composition include conventional compositions such as compositions comprising as the essential components a resin soluble in an alkali, a substance crosslinking with an acid and a compound generating an acid by irradiation with an ionizing radiation.

In the above positive type resist composition of the chemical amplification type, the resin which exhibits varying solubility into an alkali by the effect of an acid is a resin obtained from a resin soluble in the alkali in a manner such that at least a portion of the group providing the solubility into the alkali such as phenolic hydroxyl group and carboxyl group in the resin soluble in an alkali is protected with a substituent which dissociates by the effect of an acid so that the protected group becomes hardly soluble in the alkali. Examples of the resin soluble in an alkali include resins of the novolak type obtained by condensation of a phenol such as phenol, m-cresol, p-cresol, xylenol and trimethylphenyl and an aldehyde such as formaldehyde in the presence of an acidic catalyst; polyhydroxystyrene-based resins such as the homopolymer of hydroxystyrene, copolymers of hydroxystyrene with other styrenic monomers and copolymers of hydroxystyrene with acrylic acid, methacrylic acid or a derivative thereof; and acrylic acid-based resins and methacrylic acid-based resins which are copolymers of acrylic acid, methacrylic acid or a derivative thereof.

Examples of the resin soluble in an alkali and having hydroxyl group protected with a substituent which dissociates by the effect of an acid include homopolymers of hydroxystyrene in which a portion of hydroxyl group and hydroxyl group in an acidic group such as carboxyl group in the resin is protected with a substituent which dissociates by the effect of an acid, copolymers of the above hydroxystyrene with other styrenic monomers, copolymers of the above hydroxystyrene with acrylic acid, methacrylic acid or a derivative thereof and copolymers of acrylic acid, methacrylic acid or a derivative thereof in which a portion of carboxyl group or hydroxyl group is protected with a substituent which dissociates by the effect of an acid and hydroxystyrene or hydroxystyrene in which a portion of hydroxyl group is protected with a substituent which dissociates by the effect of an acid.

Examples of the substituent which dissociates by the effect of an acid include alkoxycarbonyl groups such as tert-butoxycarbonyl group and tert-amyloxycarbonyl group; tertiary alkyl groups such as tert-butyl group; alkoxyalkyl groups such as ethoxyethyl group and methoxypropyl group; acetal groups such as tetrahydropyranyl group and tetrahydrofuranyl group; benzyl group; trimethylsilyl group; 2-propenyl groups having 2 or more substituents; and cycloalkyl groups having a substituent at the 1-position such as 1-ethylcyclohexyl group.

The fraction of the hydroxyl groups protected with the substituent which dissociates by the effect of an acid is, in general, in the range of 1 to 60% by mole and preferably in the range of 5 to 50% by mole of the hydroxyl groups in the resin.

The compound generating an acid by irradiation with an ionizing radiation (referred to as an agent generating an acid, hereinafter) is not particularly limited and a suitable compound can be selected from conventional compounds which are used as the agent for generating an acid for resists of the chemical amplification type. Examples of the agent generating an acid include bissulfonyldiazomethanes such as bis(p-toluenesulfonyl)diazomethane; nitrobenzyl derivatives such as 2-nitrobenzyl p-toluenesulfonate; esters of sulfonic acid such as pyrogallol trimesylate; onium salts such as diphenyliodonium hexafluorophosphate; benzoin tosylates such as benzoin tosylate; triazine compounds having halogens such as 2-(4-methoxyphenyl)-4,6-(bistrichloromethyl)-1,3,5-triazine; and oximesulfonate compounds having cyano group such as α-(methylsulfonyloxyimino)phenylacetonitrile.

The agent generating an acid may be used singly or in combination or two or more. The amount is in the range of 0.5 to 30 parts by weight and preferably in the range of 1 to 10 parts by weight per 100 parts by weight of the above resin which exhibits varying solubility into an alkali by the effect of an acid. When the amount of the agent generating an acid is less than the above range, an image is not formed. When the amount of the agent for generating an acid exceeds the above range, a uniform solution is not formed and the storage stability decreases.

In the negative type resist composition of the chemical amplification type, examples of the resin soluble in an alkali include phenol novolak resins, cresol novolak resins and hydroxystyrene-based resins such as polyhydroxystyrene and copolymers of hydroxystyrene with a monomers copolymerizable with hydroxystyrene. Examples of the hydroxystyrene resin include the homopolymer of hydroxystyrene; copolymers of hydroxystyrene with derivatives of acrylic acid, acrylonitrile, derivatives of methacrylic acid, methacrylonitrile or derivatives of styrene such as styrene, α-methylstyrene, p-methylstyrene, o-methylstyrene, p-methoxy-styrene and p-chlorostyrene; hydrogenated resins of the homopolymer of hydroxystyrene; and hydrogenated resins of copolymers of hydroxystyrene with derivatives of acrylic acid, derivatives of methacrylic acid or derivatives of styrene described above. Resins in which a portion of hydroxyl group and hydroxyl group in an acidic group such as carboxyl group is protected with the substituent which dissociates by the effect of an acid can also be used advantageously.

As the substance crosslinking with an acid, melamine resins, epoxy compounds and urea resins modified with N-methyl group or an alkoxymethyl group which are conventionally used as the crosslinking agent in the negative type resins of the chemical amplification type can be used singly or as a mixture or two or more.

Examples of the agent generating an acid include the same compounds which are described as the examples of the agent generating an acid in the positive type resist composition of the chemical amplification type.

As for the amounts of the components, in general, the amount of the substance crosslinking with an acid is selected in the range of 3 to 70 parts by weight and the amount of the agent generating an acid is selected in the range of 0.5 to 20 parts by weight per 100 parts by weight of the resin soluble in an alkali. When the amount of the substance crosslinking with an acid is less than 3 parts by weight, it is difficult that the resist pattern is formed. When the amount of the substance crosslinking with an acid exceeds 70 parts by weight, the property for development becomes poor. When the amount of the agent generating an acid is less than 0.5 parts by weight, the sensitivity decreases. When the amount of the agent generating an acid exceeds 20 parts by weight, it is difficult that a uniform resist is obtained and the property for development becomes poor.

The resist composition is, in general, used as a solution prepared by dissolving the above components in a solvent. Examples of the solvent include ketones such as acetone, methyl ethyl ketone, cyclohexanone, methyl isoamyl ketone and 2-heptanone; polyhydric alcohols and derivatives thereof such as ethylene glycol, ethylene glycol monoacetate, diethylene glycol, diethylene glycol monoacetate, propylene glycol, propylene glycol monoacetate, dipropylene glycol, dipropylene glycol monoacetate and monomethyl ethers, monoethyl ethers, monopropyl ethers, monobutyl ethers and monophenyl ethers of these alcohols; cyclic ethers such as dioxane; esters such as methyl lactate, ethyl lactate, methyl acetate, ethyl acetate, butyl acetate, methyl pyruvate, ethyl pyruvate, methyl methoxypropionate and ethyl ethoxypropionate; and amides such as N,N-dimethylformamide, N,N-dimethylacetamide and N-methyl-2-pyrrolidone. The solvent may be used singly or as a mixture of two or more.

The solution of the resist composition prepared as described above may further comprise, where desired, additives compatible with the composition such as additional resins, organic amines, organic carboxylic acids, plasticizers, stabilizers, surfactants and antioxidants which are conventionally used for improving the properties, sensitivity and resolution of the resist film.

The substrate for working which is used for the substrate for forming the resist pattern of the present invention is not particularly limited and various substrates can be used in accordance with the application. Examples of the substrate for working include silicone wafers for semiconductor devices and blanks for photomasks. The shape of the substrate for working is not particularly limited and may be any of a circular shape (such as the shape of silicone wafers) or a rectangular shape (such as the shape of blanks for photomasks).

The thickness of the above resist film of the chemical amplification type formed on the substrate for working is different depending on the application. In general, the thickness is selected in the range of 10 to 1,000 nm. When the resist film is used for preparing a photomask, the thickness is in the range of 100 to 400 nm.

In the substrate for forming a resist pattern of the present invention, a coating film comprising an amorphous polyolefin or a polymer having an aromatic ring is formed on the resist film of the chemical amplification type.

This coating film is formed to shield the resist film of the chemical amplification type from the atmosphere. The coating film has the following properties: (1) highly transparent at the wavelength of the light of irradiation and transmitting particle beams such as electron beams, (2) excellent in the coating property and the property for forming a coating film, (3) not allowing permeation of impurities contained in the atmosphere and (4) chemically stable.

The above amorphous polyolefin may be substituted with fluorine atom. Examples of the amorphous polyolefin include homopolymers and copolymers of olefins such as alkenes, cycloalkanes, alkadienes and cycloalkadienes, olefins substituted with fluorine atom such as perfluoroalkenes, perfluorocycloalkenes, perfluoroalkadienes perfluorocycloalkadienes and hydrogenation products of these polymers; polymers obtained by ring opening polymerization of cycloalkenes and hydrogenation products of these polymers; addition polymers of cycloalkenes and alkenes; and addition polymers of cycloalkenes and α-olefins. The amorphous polyolefin is not particularly limited as long as the polyolefin is an amorphous substance. The amorphous polyolefin may be used singly or in combination of two or more. Among these polymers, polymers obtained by ring opening polymerization of cycloalkenes and hydrogenation products these polymers are preferable.

The coating film comprising the amorphous polyolefin exhibits the excellent coating property and a small water absorption of 0.01% or smaller and can be removed with a conventional solvent.

The polymer having an aromatic ring may be substituted with a halogen atom. Examples of the polymer having an aromatic ring include polymers of aromatic vinyl compounds such as polystyrene, poly-2-methylstyrene, poly-3-methylstyrene, poly-4-methylstyrene, poly-2-methoxystyrene, poly-3-methoxystyrene, poly-4-methoxystyrene, poly-2-chlorostyrene, poly-3-chlorostyrene, poly-4-chlorostyrene, poly-2-bromostyrene, poly-3-bromostyrene, poly-4-bromostyrene, poly-2-(chloromethyl)styrene, poly-3-(chloromethyl)styrene and poly-4-(chloromethyl)styrene. Further examples of the polymer having an aromatic ring include polymers obtained by polymerizing at least one monomer selected from aromatic ester compounds of unsaturated aliphatic carboxylic acids and, where necessary, a monomer copolymerizable with the monomer without using solvents or in a suitable solvent. Examples of the aromatic ester compounds of unsaturated aliphatic carboxylic acids include phenyl acrylate, 2-methylphenyl acrylate, 3-methylphenyl acrylate, 4-methylphenyl acrylate, 2-methoxyphenyl acrylate, 3-methoxyphenyl acrylate, 4-methoxyphenyl acrylate, 2-chlorophenyl acrylate, 3-chlorophenyl acrylate, 4-chlorophenyl acrylate, 2-bromophenyl acrylate, 3-bromophenyl acrylate, 4-bromophenyl acrylate, phenyl methacrylate, 2-methylphenyl methacrylate, 3-methylphenyl methacrylate, 4-methylphenyl methacrylate, 2-chlorophenyl methacrylate, 3-chlorophenyl methacrylate, 4-chlorophenyl methacrylate, 2-bromophenyl methacrylate, 3-bromophenyl methacrylate and 4-bromophenyl methacrylate.

Among the above polymers, polymers of aromatic vinyl compounds exhibiting a higher ability of suppressing the change in the sensitivity are preferable.

Examples of the solvent which can be used in the polymerization of the above monomers include aliphatic hydrocarbons such as hexane, cyclohexane, heptane and octane; aromatic hydrocarbons such as benzene, toluene, xylene and naphthalene; ketones such as acetone, methyl ethyl ketone and diethyl ketone; ethers such as dimethyl ether, tetrahydrofuran, dioxane and diphenyl ether; esters such as ethyl acetate, butyl acetate and ethyl benzoate; ether esters such as ethyl cellosolve acetate and propylene glycol monomethyl ether acetate; and amides such as dimethylacetamide, dimethylformamide and hexamethylphosphoric acid triamide. As the catalyst, various polymerization initiators such as azobisisobutyronitrile, dicumyl peroxide, butyllithium, methyllithium and ethyllithium can be used.

The polymer having an aromatic ring exhibits the excellent coating property and can be applied to the resist film uniformly with excellent adhesion. The polymer having an aromatic ring may be used singly or in combination of two or more.

In the substrate for forming a resist pattern of the present invention, it is necessary that the thickness of the coating film comprising the above amorphous polyolefin or the above polymer having an aromatic ring be the same as or smaller than the thickness of the resist film of the chemical amplification type on which the coating film is formed. When the thickness of the coating film exceeds the thickness of the resist film, an excellent pattern shape cannot be obtained and resolution deteriorates since scattering of particles takes place while particles pass through the coating film when particle beams such as electron beams is used for forming a pattern. It is preferable that the thickness of the coating film is 90% or smaller and more preferably 80% or smaller of the thickness of the resist film. When the thickness is excessively small, there is the possibility that the effect of the coating film is not sufficiently exhibited. Therefore, it is preferable that the thickness of the coating film is 0.05% or greater, more preferably 0.1% or greater and most preferably 0.5% or greater of the thickness of the resist film.

The substrate for forming a resist pattern of the present invention can be produced in accordance with the process of the present invention comprising steps of: (A) forming a resist film of the above chemical amplification type on a substrate for working and (B) forming on the above resist film of the chemical amplification type a coating film which comprises an amorphous polyolefin or a polymer having an aromatic ring and has a thickness which is the same as or smaller than the thickness of the resist film.

In the above step (A), a substrate for working is coated with the above solution of the resist composition of the chemical amplification type and the resist film of the chemical amplification types is formed by the heating treatment of the formed coating film. As the process for the coating, in general, the spin coating process is preferably used. The heating treatment is conducted to remove the solvent and dry the coating film. The temperature of heating is, in general, in the range of about 60 to 160° C. and it is sufficient that the time of heating is in the range of about 1 to 30 minutes.

In the above step (B), the above amorphous polyolefin or the above polymer having an aromatic ring is dissolved in a suitable solvent. Where necessary, the resultant solution is filtered with a filter and a coating fluid is prepared. The coating fluid is applied to the resist film of the chemical amplification type in accordance with the spin coating process. The formed coating film is dried by heating at a temperature in the range of about 60 to 130° C. and the desired coating film is formed. It is preferable that a solvent which does not dissolve or hardly dissolves the resist film is selected as the above solvent. Examples of the solvent include aliphatic hydrocarbons such as n-hexane, cyclohexane, n-heptane, methyl-cyclohexane, n-octane, isooctane, n-decane, decaline and ligroine; aromatic hydrocarbons such as benzene, toluene, xylene, ethylbenzene, isopropylbenzene and diethylbenzene; and halogenated aliphatic hydrocarbons such as carbon tetrachloride, chloroform, trichloroethane, perfluoropentane and perfluorohexane. The solvent may be used singly or as a mixture of two or more. Ethers and esters may be further added to the above solvent. It is preferable that a solvent having a boiling point in the range of 80 to 200° C. and more preferably in the range of 100 to 150° C. is selected among the above solvents so that the excellent coating property can be exhibited. The coating property can be improved by adding various types of surfactants such as silicone-based surfactants, fluorine-based surfactants and nonionic surfactants which can also be added to the resist composition described above. The amount of the surfactant is, in general, in the range of 1 to 100 ppm and preferably in the range of 5 to 50 ppm.

The present invention further provides a coating composition for forming a coating film on a resist film of the chemical amplification type which comprises the above amorphous polyolefin or the above polymer having an aromatic ring and the above solvent.

The process for forming a resist pattern of the chemical amplification type of the present invention comprises steps of (C) forming a pattern of a latent image in a resist film of the chemical amplification type by irradiation of a substrate for forming a resist pattern of the present invention described above with an ionizing radiation and (D) converting the pattern of a latent image into a pattern of a visible image by a development treatment of the resist film having the pattern of a latent image.

Examples of the ionizing radiation used in the above step include ultraviolet light, g ray, i ray, KrF excimer laser, ArF excimer laser and particle beams such as electron beams. The process for irradiating the resist film of the chemical amplification type with the ionizing radiation to achieve selective exposure or to form a pattern is not particularly limited and a conventional process can be used. For example, the resist film of the chemical amplification type may be irradiated with ultraviolet light, g ray, i ray, KrF excimer laser or ArF excimer laser through a desired mask pattern using an reduced projection exposure apparatus. Alternatively, a pattern may be formed using particle beams such as electron beams. The formation of a pattern using particle rays is preferable since a pattern having an excellent shape can be obtained. A pattern of a latent image is formed in the resist film as described above.

In the present invention, step (C) may be conducted immediately after step (B) is conducted in the process for producing a substrate for forming a resist pattern described above or after the resist film prepared in step (B) in the above process is left standing for a suitable period of time such as several months.

It is preferable that the resist film is treated by heating at a temperature in the range of about 60 to 130° C. for about 1 to 30 minutes after step (C) is conducted and before step (D) is conducted or, when step (C′) described in the following is conducted before step (D), before step (C′) is conducted.

In the process of the present invention, when the coating film formed on the resist film is not dissolved with a development liquid and removed in step (D), the coating film formed on the resist film having the latent image in step (C) is removed in step (C′). When the coating film comprises the amorphous polyolefin, it is necessary that step (C′) be conducted. When the coating film comprises the polymer having an aromatic ring, the coating film is occasionally dissolved with the solvent and removed in the development treatment. In this case, it is not necessary that step (C′) is conducted.

In step (C′), the spin cleavage process with a solvent can be used for removing the coating film. As the solvent used for this step, the same solvents as those described as the examples in the preparation of the coating fluid containing the amorphous polyolefin or the polymer having an aromatic ring in step (B) can be used. The solvent for the removal may be used singly or in combination of two or more.

After the coating film has been removed, it is preferable that the resist film is treated again by heating at a temperature in the range of about 60 to 130° C. for about 1 to 30 minutes before step (D) is conducted.

Step (D) in the process of the present invention is a step in which the resist film of the chemical amplification type having the pattern of a latent image after the treatment in step (C) or step (C′) described above is subjected to the development treatment and the pattern of a latent image is converted into a pattern of a visible image. The development treatment in this step is not particularly limited and a conventional process can be used. For example, the development treatment is conducted using an alkaline aqueous solution such as a 1 to 10% by weight aqueous solution of tetramethyl ammonium hydroxide. After the development treatment has been conducted, in general, the resist film is subjected to a rinsing treatment using pure water.

The resist pattern having a rectangular sectional shape and exhibiting excellent dimensional fidelity can be obtained as described above.

In the process for producing a semiconductor device or a member used for producing a semiconductor device of the present invention, the step of etching and the step of removing the resist pattern are conducted successively after the steps of forming a resist pattern described above.

Specifically, using the resist pattern formed as described above as the mask, an underlayer film is treated by dry etching using a fluorine-based gas such as CF₄ or a chlorine-based gas such as Cl₂/O₂ or by wet etching using an aqueous solution of ammonium serine nitrate. Then, the resist pattern is removed with a liquid for removing a resist and a semiconductor device or a member used for producing a semiconductor device and preferably a photomask is produced. When a photomask is produced, pellicle coating can also be conducted so that formation of scratches on the surface of the photomask during the production can be prevented.

In accordance with the present invention, a substrate for forming a resist pattern which suppresses deterioration in sensitivity and resolution with time during storage and transportation of the resist film of the chemical amplification type formed on the substrate, has a rectangular sectional shape and provides the resist pattern of the chemical amplification type having excellent dimensional fidelity, can be provided.

By using this substrate for forming a resist pattern, a resist pattern of the chemical amplification type which is advantageously used for producing a semiconductor device and a member used for producing semiconductor devices and, in particular, for producing a photomask can be formed with excellent sensitivity and excellent resolution.

### EXAMPLES

The present invention will be described more specifically with reference to examples in the following. However, the present invention is not limited to the examples.

### Example 1

As the positive type resist of the chemical amplification type, a resist composition comprising 100 parts by weight of polyhydroxystyrene having a weight-average molecular weight of 5,400 in which 25% by mole of hydroxyl group was protected with tert-butoxycarbonyl group, 5 parts by weight of triphenylsulfonium trifluoromethanesulfonate, 0.09 parts by weight of tributylamine and 1,000 parts by weight of propylene glycol monomethyl ether acetate was used.

A circular silicone substrate having a diameter of 10 cm was coated with the above positive type resist of the chemical amplification type in accordance with spin coating process. The coated substrate was treated by heating at 95° C. for 110 seconds and a resist film having a thickness of 500 nm was formed. Then, on the formed resist film, a 3% by weight xylene solution of “ZEONEX 480” [a trade name; manufactured by ZEON Corporation] as the amorphous polyolefin resin was applied in accordance with the spin coating process. The resultant product was treated by heating at 60° C. for 80 seconds and a coating film having a thickness of 400 nm was formed.

When 1 minute passed after the formation of the coating film, an L/S pattern of 0.5 μm was drawn at a dose of 2.2 μC/cm² using a drawing apparatus with electron beams [manufactured by ELIONIX Inc.; the trade name: ELS-3300]. The obtained product was treated by the spin cleavage with xylene for 15 seconds and the coating film of the polyolefin resin was removed. The resultant product was treated by heating at 90° C. for 110 seconds on a hot plate and subjected to the development treatment with a 2.38% by weight aqueous solution of tetramethylammonium hydroxide for 90 seconds and then to the rinsing treatment with pure water for 10 seconds.

The sectional shape of the resist pattern obtained as described above was observed by a scanning electron microscope (SEM) and found to be a rectangular shape.

### Examples 2 to 6

The same procedures as those conducted in Example 1 were conducted except that the thickness of the coating film of the polyolefin resin and the time before the exposure to the electron beams after the formation of the coating film were set as shown in Table 1. The results are shown in Table 1.

It was found that the sectional shape of the resist pattern was kept at a rectangular shape when the ratio of the thickness is 1 or smaller.

### Comparative Example 1

The same procedures as those conducted in Example 1 were conducted except that the ratio of the thickness was changed to 1.6. The result is shown in Table 1.

When the ratio of the thickness was set at 1.6, the effect of scattering of electron beams in the coating film (deterioration in the shape) was found.

TABLE 1

| | Thickness of | | | |
|---|---|---|---|---|
| | coating film | Ratio of | Time before | Sectional shape |
| | (nm) | thickness¹⁾ | exposure²⁾ | of pattern |
| Example 1 | 400 | 80 | 1 minute | rectangular |
| Example 2 | 400 | 80 | 1 week | rectangular |
| Example 3 | 400 | 80 | 3 months | rectangular |
| Example 4 | 100 | 20 | 3 months | rectangular |
| Example 5 | 20 | 4 | 3 months | rectangular |
| Example 6 | 2 | 0.4 | 1 minute | rectangular |
| | | | 1 week | rectangular |
| | | | 3 months | inverse tapered |
| | | | | shape with small |
| | | | | hoods |
| Comparative | 800 | 160 | 1 minute | tails |
| Example 1 | | | | |

[Note]
¹⁾Ratio of thickness: (thickness of coating film/thickness of resist film) × 100
²⁾Time before exposure: the time before the exposure to the electron beams after the formation of the coating film.

### Example 7

As the positive type resist of the chemical amplification type, a resist composition comprising 100 parts by weight of polyhydroxystyrene having a weight-average molecular weight of 5,400 in which 25% by mole of hydroxyl group was protected with tert-butoxycarbonyl group, 5 parts by weight of triphenylsulfonium trifluoromethanesulfonate, 0.09 parts by weight of tributylamine and 1,000 parts by weight of propylene glycol monomethyl ether acetate was used.

A circular silicone substrate having a diameter of 10 cm was coated with the above positive type resist of the chemical amplification type in accordance with spin coating process. The coated substrate was treated by heating at 95° C. for 110 seconds and a resist film having a thickness of 400 nm was formed. Separately, a 4% by weight xylene solution of a styrene polymer [the degree of polymerization: about 3,000; manufactured by WAKO PURE CHEMICAL INDUSTRIES, Ltd.] was prepared and a surfactant KP-341 [manufactured by SHIN-ETSU CHEMICAL Co., Ltd.] was added to the prepared solution in an amount such that the concentration was 25 ppm. The obtained solution was filtered through a PTFE membrane filter having a pore size of 0.2 μm and a xylene solution of polystyrene was prepared. The prepared xylene solution of polystyrene was applied to the resist film in accordance with the spin coating process. The formed coating film was treated by heating at 60° C. for 80 seconds (prebaking) and a protective film having a thickness of 100 nm was formed. The resultant product was left standing in an environment having a concentration of ammonia of 50 ppb for 1 minute after the formation of the coating film. Twenty square patterns having sides of 25 μm were drawn at doses increasing from 2.0 μC/cm² to 2.95 μC/cm² with an increment of 0.05 μC/cm² using a drawing apparatus with electron beams [manufactured by ELIONIX Inc.; the trade name: ELS-3300]. The obtained product was treated by the spin cleavage with xylene for 15 seconds and the coating film of the polyolefin resin was removed. The resultant product was treated by heating on a hot plate at 90° C. for 110 seconds (post baking) and subjected to the development treatment with a 2.38% by weight aqueous solution of tetramethylammonium hydroxide for 90 seconds and then to the rinsing treatment with pure water for 10 seconds. The dose which gave complete removal of the resist film was defined as the sensitivity. In this case, the dose of 2.25 μC/cm² corresponded to the sensitivity.

### Example 8 and 9

The same procedures as those conducted in Example 7 were conducted except that the time left standing after the formation of the protective film was changed as shown in Table 2. The results are shown in Table 2.

### Comparative Example 2

The same procedures as those conducted in Example 7 were conducted except that, after the resist film was formed, the obtained product was left standing in an environment having a concentration of ammonia of 50 ppb for 1 minute without forming the protective film and then the sensitivity was obtained. The result is shown in Table 2.

TABLE 2

| | Thickness of | | |
|---|---|---|---|
| | coating film | Time before | Sensitivity |
| | (nm) | exposure¹⁾ | (μC/cm²) |
| Example 7 | 100 | 1 minute | 2.25 |
| Example 8 | 100 | 1 week | 2.25 |
| Example 9 | 100 | 3 months | 2.25 |
| Comparative | — | 1 minute | 2.95 |
| Example 2 | | | or greater |

[Notes]
¹⁾Time before exposure: the time before the exposure to electron beams after the formation of the coating film.

It is shown by the results in Table 2 that higher sensitivities were obtained in Examples 7 to 9 than that in Comparative Example 2 and no change in the sensitivity was found after being left standing in the environment having a concentration of ammonia of 50 ppb for 3 months.

What is claimed is:

1. A substrate for forming a resist pattern comprising a resist film of a chemical amplification type and a coating film which is formed on the resist film, comprises an amorphous polyolefin or a polymer having an aromatic ring and has a thickness which is a same as or smaller than a thickness of the resist film.

2. A substrate according to claim 1, wherein the coating film comprises the amorphous polyolefin which may be substituted with fluorine atom.

3. A substrate according to claim 1, wherein the coating film comprises the polymer having an aromatic ring, wherein the polymer may be substituted with a halogen atom.

4. A substrate according to claim 1, wherein the amorphous polyolefin is a polymer obtained by ring opening polymerization of a cycloalkene or a hydrogenation product of the obtained polymer.

5. A substrate according to claim 1, wherein the polymer having an aromatic ring is a polymer of an aromatic vinyl compound.

6. A substrate according to claim 1, wherein the coating film has a thickness which is 0.05 to 90% of the thickness of the resist film of a chemical amplification type.

7. A process for producing a substrate for forming a resist pattern, which comprises steps of (A) forming a resist film of a chemical amplification type on a substrate for working and (B) forming on the resist film a coating film which comprises an amorphous polyolefin or a polymer having an aromatic ring and has a thickness which is a same as or smaller than a thickness of the resist film.

8. A process according to claim 7, wherein, in step (B), the coating film is formed by coating the resist film with a solution prepared by dissolving the amorphous polyolefin or the polymer having an aromatic ring into a solvent having a boiling point of 80 to 200° C. and drying the coating solution.

9. A composition for forming a coating film on a resist film of a chemical amplification type, which comprises an amorphous polyolefin or a polymer having an aromatic ring and a solvent.

10. A process for forming a resist pattern of a chemical amplification type, which comprises steps of (C) forming a pattern of a latent image in a resist film of a chemical amplification type by irradiation of a substrate for forming a resist pattern described in claim 1 with an ionizing radiation and (D) converting the pattern of a latent image into a pattern of a visible image by a development treatment of the resist film having the pattern of a latent image.

11. A process according to claim 10, wherein the ionizing radiation used in step (C) is particle beams.

12. A process according to claim 10, wherein the coating film formed on the resist film is removed after the pattern of a latent image is formed in the resist film in step (C).

13. A process according to claim 12, wherein the substrate is treated by heating at 60 to 130° C. after the pattern of a latent image is formed in the resist film in step (C) and before the coating film formed on the resist film is removed.

14. A process according to claim 12, wherein the coating film formed on the resist film is removed and then the substrate is treated by heating at 60 to 130° C. after the pattern of a latent image is formed in the resist film in step (C).

15. A process for producing a semiconductor device or a member used for producing a semiconductor device, which comprises steps of forming a resist pattern as described in claim 10, etching a substrate and removing the resist pattern, successively.

16. A process according to claim 15, wherein the member used for producing a semiconductor device is a photomask.
